(19) United States
(12) Patent Application Publication
(10) Pub. No.: US 2024/0172541 A1
(43) Pub. Date: May 23, 2024

(54) DISPLAY APPARATUS

(71) Applicant: Samsung Display Co., LTD., Yongin-si, Gyeonggi-do (KR)

(72) Inventors: Seungyeon Jeong, Yongin-si (KR); Ohjeong Kwon, Yongin-si (KR); Hyeoji Kang, Yongin-si (KR); Taeho Kim, Yongin-si (KR); Duckjong Suh, Yongin-si (KR); Mihwa Lee, Yongin-si (KR); Hongyeon Lee, Yongin-si (KR)

(21) Appl. No.: 18/503,669

(22) Filed: Nov. 7, 2023

(30) Foreign Application Priority Data
Nov. 10, 2022 (KR) 10-2022-0149644

(51) Int. Cl. H10K 59/80

(52) U.S. Cl. CPC H10K 59/8792

(57) ABSTRACT

Provided is a display apparatus including a substrate, a display element on the substrate and defining an emission area, a low-reflection layer on the display element and including an inorganic material, a light blocking layer including a first sub-light blocking layer on the low-reflection layer and a second sub-light blocking layer on the first sub-light blocking layer, the light blocking layer having an opening passing through the first sub-light blocking layer and the second sub-light blocking layer to correspond to the emission area, and a reflection control layer on the light blocking layer and filling the opening. The first sub-light blocking layer includes a metal material, and the second sub-light blocking layer includes a metal material and/or a metal oxide.

### CROSS-REFERENCE TO RELATED APPLICATION

This application claims priority to and the benefit of Korean Patent Application No. 10-2022-0149644, filed on Nov. 10, 2022, in the Korean Intellectual Property Office, the entire content of which is incorporated by reference herein in its entirety.

### BACKGROUND

### 1. Field

One or more embodiments of the present disclosure relate to a display apparatus, and, for example, to a display apparatus having improved visibility.

### 2. Description of the Related Art

Organic light-emitting display apparatuses have self-luminescence properties and, unlike liquid crystal display devices, do not require a separate light source. Accordingly, the thickness and weight of the organic light-emitting display apparatuses may be reduced. Also, the organic light-emitting display apparatuses exhibit high quality characteristics, such as low power consumption, high luminance, and fast response time.

### SUMMARY

However, in existing display apparatuses, visibility deteriorates due to reflection of external light.

One or more embodiments of the present disclosure include a display apparatus with improved visibility, the display apparatus including a low-reflection layer and a reflection control layer on a display element. However, this is merely an example, and the scope of the disclosure is not limited thereby.

Additional aspects of embodiments will be set forth in part in the description which follows and, in part, will be apparent from the description, or may be learned by practice of the presented embodiments of the disclosure.

According to one or more embodiments, a display apparatus includes a substrate, a display element on the substrate and defining an emission area, a low-reflection layer on the display element and including an inorganic material, a light blocking layer including a first sub-light blocking layer on the low-reflection layer and a second sub-light blocking layer on the first sub-light blocking layer, the light blocking layer having an opening passing through the first sub-light blocking layer and the second sub-light blocking layer to correspond to the emission area, and a reflection control layer on the light blocking layer and filling the opening, wherein the first sub-light blocking layer includes a metal material, and the second sub-light blocking layer includes a metal material and/or a metal oxide.

In an embodiment, the first sub-light-blocking layer may have a light reflectance of 95% or more, and the second sub-light-blocking layer may have an extinction coefficient (k) greater than 0.5 and less than or equal to 4.0 (0.5<k≤4.0).

In an embodiment, the first sub-light blocking layer may have a first thickness of about 40 Å to about 1,500 Å, and the second sub-light blocking layer may have a second thickness of about 150 Å to about 1,000 Å.

In an embodiment, the light blocking layer may include an auxiliary layer, and the auxiliary layer may include a transparent conductive material and/or silicon nitride.

In an embodiment, the auxiliary layer may be between the first sub-light blocking layer and the second sub-light blocking layer.

In an embodiment, the auxiliary layer may be between the low-reflection layer and the first sub-light blocking layer.

In an embodiment, the auxiliary layer may have a thickness of about 50 Å to about 100 Å.

In an embodiment, the low-reflection layer may include at least one selected from a metal material and a metal oxide, and the low-reflection layer may have a refractive index (n) of 1 or more.

In an embodiment, the display apparatus may further include a capping layer on the display element and including an organic material, wherein the low-reflection layer may be directly on the capping layer.

In an embodiment, the reflection control layer may include a dye, a pigment, or any combination thereof.

In an embodiment, the display apparatus may further include a thin-film encapsulation layer on the low-reflection layer, and a touch sensing layer on the thin-film encapsulation layer, wherein the light blocking layer is on the touch sensing layer.

According to one or more embodiments, a display apparatus includes a first substrate, a display element on the first substrate and defining an emission area, a low-reflection layer on the display element and including an inorganic material, a second substrate above the first substrate with the display element and the low-reflection layer therebetween, a light blocking layer including a second sub-light blocking layer on a lower surface of the second substrate facing the first substrate and a first sub-light blocking layer on a lower surface of the second sub-light blocking layer facing the first substrate, the light blocking layer having an opening passing through the first sub-light blocking layer and the second sub-light blocking layer to correspond to the emission area, and a reflection control layer between the light blocking layer and the low-reflection layer and filling the opening, wherein the first sub-light blocking layer includes a metal material, and the second sub-light blocking layer includes a metal material and/or a metal oxide.

In an embodiment, the first sub-light-blocking layer may have a light reflectance of 95% or more, and the second sub-light-blocking layer may have an extinction coefficient (k) greater than 0.5 and less than or equal to 4.0 (0.5<k≤4.0).

In an embodiment, the first sub-light blocking layer may have a first thickness of about 40 Å to about 1,500 Å, and the second sub-light blocking layer may have a second thickness of about 150 Å to about 1,000 Å.

In an embodiment, the light blocking layer may include an auxiliary layer, and the auxiliary layer may include a transparent conductive material and/or silicon nitride.

In an embodiment, the auxiliary layer may have a thickness of about 50 Å to about 100 Å.

In an embodiment, the low-reflection layer may include at least one selected from a metal material and a metal oxide, and the low-reflection layer may have a refractive index (n) of 1 or more.

In an embodiment, the display apparatus may further include a capping layer on the display element and including an organic material, wherein the low-reflection layer may be directly on the capping layer.

In an embodiment, the reflection control layer may include a dye, a pigment, or any combination thereof.

In an embodiment, the display apparatus may further include a filler between the low-reflection layer and the reflection control layer.

Other aspects and features of embodiments of the disclosure will become better understood through the accompanying drawings, the claims, and the detailed description.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a perspective view schematically illustrating a display apparatus according to an embodiment;

FIG. 2 is a circuit diagram schematically illustrating a display element and a pixel circuit connected thereto in a pixel of a display apparatus, according to an embodiment;

FIGS. 3A-3B are respectively cross-sectional views schematically illustrating display apparatuses according to embodiments;

FIGS. 4A-4B are respectively plan views schematically illustrating pixel arrangements of a display apparatus, according to embodiments;

FIG. 5 is a cross-sectional view schematically illustrating a portion of a display apparatus, according to an embodiment;

FIGS. 6A-6B are respectively cross-sectional views schematically illustrating a portion of display apparatuses, according to embodiments;

FIG. 7 is a graph showing light transmittance of a reflection control layer, according to an embodiment;

FIG. 8 is a cross-sectional view schematically illustrating a portion of a display apparatus, according to an embodiment;

FIGS. 9A-9B are respectively cross-sectional views schematically illustrating a portion of display apparatuses, according to embodiments;

FIG. 10 is a graph showing reflectance for each wavelength in a display apparatus according to a comparative example and display apparatuses according to experimental examples; and

FIGS. 11A-11B are graphs showing a relationship between thicknesses of a first sub-light blocking layer and a second sub-light blocking layer, which have a minimum reflectance in a short wavelength band.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, example embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in more detail in the written description. Effects and features of the disclosure, and methods of achieving them will be clarified with reference to embodiments described below in more detail with reference to the drawings. However, the disclosure is not limited to the following embodiments and may be embodied in various suitable forms.

Hereinafter, embodiments will be described in more detail with reference to the accompanying drawings. When describing embodiments with reference to the accompanying drawings, the same or corresponding elements are denoted by the same reference numerals.

It will be understood that although the specification, the terms “first,” “second,” etc. may be used herein to describe various elements, these elements should not be limited by these terms. These terms are only used to distinguish one element from another.

The singular forms “a,” “an,” and “the” as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. For example, intervening layers, regions, or elements may be present.

It will be further understood that when layers, regions, or elements are referred to as being connected to each other, they may be directly connected to each other or indirectly connected to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

In this specification, the expression “A and/or B” indicates only A, only B, or both A and B. In this specification, the expression “at least one of A and B” indicates only A, only B, or both A and B.

In the present specification, the x-axis, the y-axis, and the z-axis are not limited to three axes of the rectangular coordinate system and may be interpreted in a broader sense. For example, the x-axis, the y-axis, and the z-axis may be perpendicular (e.g., substantially perpendicular) to one another or may represent different directions that are not perpendicular (e.g., substantially perpendicular) to one another.

When a certain embodiment may be implemented differently, a set or specific process order may be performed differently from the described order. For example, two consecutively described processes may be performed substantially at the same time or performed in an order opposite to the described order.

Also, sizes of elements in the drawings may be exaggerated or reduced for convenience of explanation. For example, because sizes and thicknesses of elements in the drawings may be arbitrarily illustrated for convenience of explanation, the disclosure is not limited thereto.

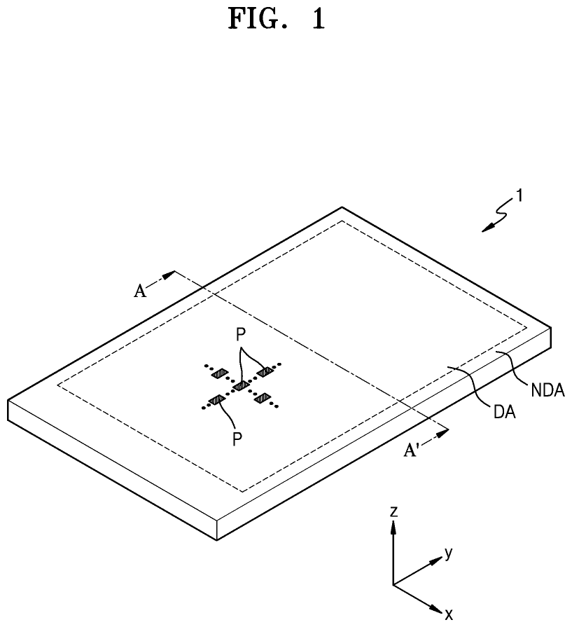

FIG. 1 is a perspective view schematically illustrating a display apparatus 1 according to an embodiment.

Referring FIG. 1, the display apparatus 1 according to an embodiment may include a display area DA and a non-display area NDA outside the display area DA. FIG. 1 illustrates that the display area DA has a substantially rectangular shape, but the disclosure is not limited thereto. The display area DA may have various suitable shapes, for example, a circular shape, an elliptical shape, or a polygonal shape.

The display area DA is a portion that allows an image to be displayed, and a plurality of pixels P may be arranged in the display area DA. Hereinafter, the “pixel” in the present specification may refer to a “sub-pixel.” The pixels P may each include a light-emitting element, such as an organic light-emitting diode. The pixels P may each emit, for example, red light, green light, blue light, or white light.

The display area DA may provide a certain image through light emitted from the pixels P. The pixel P as used herein may be defined as an emission area that emits one selected from red light, green light, blue light, and white light, as described herein.

The non-display area NDA is an area in which the pixels P are not arranged and through which an image is not provided. A terminal part, to which a printed circuit board or a driver integrated circuit (IC) including a driving circuit and a power supply line for driving the pixels P is connected, may be arranged in the non-display area NDA.

Hereinafter, an organic light-emitting display will be described as an example of the display apparatus 1 according to an embodiment. However, the display apparatus 1 according to an embodiment is not limited thereto. Examples of the display apparatus according to an embodiment may include an inorganic light-emitting display (or an inorganic electroluminescence (EL) display), a quantum dot light-emitting display, and/or the like. For example, an emission layer included in the light-emitting element of the display apparatus 1 may include an organic material and/or an inorganic material. Also, quantum dots may be positioned on a path of light emitted from the emission layer.

The display apparatus 1 according to an embodiment may be used in portable electronic devices, such as mobile phones, smartphones, tablet personal computers (PCs), mobile communication terminals, electronic organizers, e-books, portable multimedia players (PMPs), navigations, and ultra mobile PCs (UMPCs). Also, the display apparatus 1 according to an embodiment may be used in various suitable products, such as televisions, laptops, monitors, billboards, and Internet of things (IoT) devices. The display apparatus 1 according to an embodiment may be applied to wearable devices, such as smart watches, watch phones, glasses-type displays, and head mounted displays (HMDs). Also, the display apparatus 1 according to an embodiment may be used in dashboards of automobiles, center information displays (CIDs) on the center fascia or dashboards of automobiles, room mirror displays replacing side mirrors of automobiles, and electronic devices on the rear sides of front seats to serve as entertainment devices for backseat passengers of automobiles.

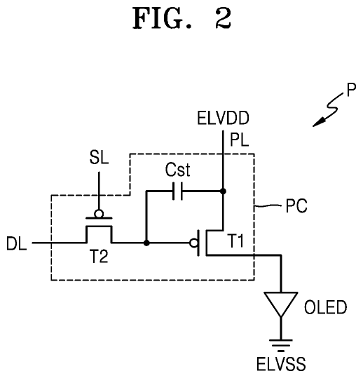

FIG. 2 is a circuit diagram schematically illustrating a display element and a pixel circuit PC connected thereto in a pixel P of a display apparatus, according to an embodiment.

Referring to FIG. 2, an organic light-emitting diode OLED, which is the display element, is connected to the pixel circuit PC. The pixel circuit PC may include a first thin-film transistor T1, a second thin-film transistor T2, and a storage capacitor Cst. The organic light-emitting diode OLED may be configured to emit, for example, red light, green light, or blue light, or may be configured to emit, for example, red light, green light, blue light, or white light.

The second thin-film transistor T2 acts as a switching thin-film transistor. The second thin-film transistor T2 may be connected to a scan line SL and a data line DL, and may be configured to transmit, to the first thin-film transistor T1, a data voltage input from the data line DL in response to a switching voltage input from the scan line SL. The storage capacitor Cst may be connected to the second thin-film transistor T2 and a driving voltage line PL, and may be configured to store a voltage corresponding to a difference between a voltage received from the second thin-film transistor T2 and a first power supply voltage ELVDD supplied to the driving voltage line PL.

The first thin-film transistor T1 acts as a driving thin-film transistor. The first thin-film transistor T1 may be connected to the driving voltage line PL and the storage capacitor Cst, and may be configured to control a driving current flowing from the driving voltage line PL to the organic light-emitting diode OLED according to a voltage value stored in the storage capacitor Cst. The organic light-emitting diode OLED may be configured to emit light having a certain luminance according to the driving current. An opposite electrode (e.g., a cathode) of the organic light-emitting diode OLED may be configured to receive a second power supply voltage ELVSS.

FIG. 2 illustrates that the pixel circuit PC includes two thin-film transistors and one storage capacitor, but in another embodiment, the number of thin-film transistors or the number of storage capacitors may be variously changed according to the design of the pixel circuit PC.

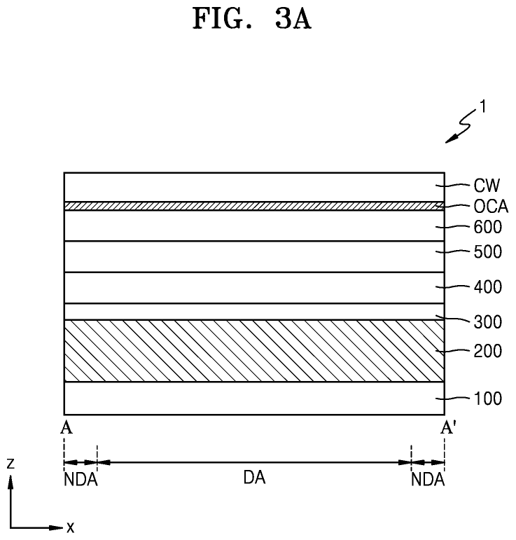

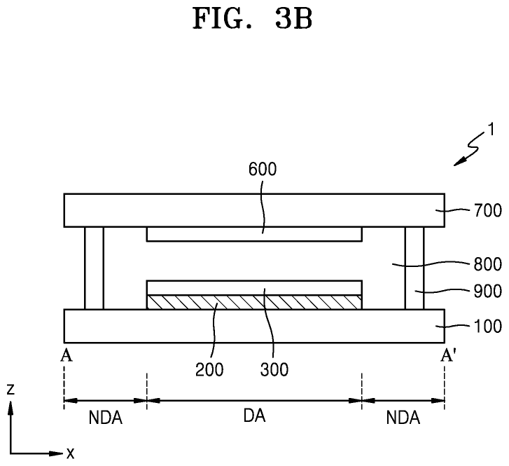

FIGS. 3A-3B are respectively cross-sectional views schematically illustrating display apparatuses 1 according to embodiments. FIGS. 3A-3B are respectively cross-sectional views of the display apparatus 1 illustrated in FIG. 1 taken along line A-A′ of FIG. 1.

Referring to FIG. 3A, the display apparatus 1 according to an embodiment may include a substrate 100, a display layer 200, a low-reflection layer 300, a thin-film encapsulation layer 400, a touch sensing layer 500, an anti-reflection layer 600, and a cover window CW.

The substrate 100 may include glass and/or polymer resin. Examples of the polymer resin may include polyethersulfone, polyacrylate, polyether imide, polyethylene naphthalate, polyethylene terephthalate, polyphenylene sulfide, polyarylate, polyimide, polycarbonate, and/or cellulose acetate propionate. The substrate 100 including the polymer resin may be flexible, rollable, and/or bendable. The substrate 100 may have a multilayer structure including a polymer resin-containing layer and an inorganic layer.

The display layer 200 may include an organic light-emitting diode as a display element, a pixel circuit electrically connected to the organic light-emitting diode, and insulating layers therebetween. Also, the display layer 200 may include scan lines, data lines, and power supply lines, which are connected to the pixel circuit, and may include a scan driver configured to apply scan signals to the scan lines and fan-out lines configured to connect the data lines to the display driver.

The low-reflection layer 300 may be on the display layer 200, and the thin-film encapsulation layer 400 may be on the low-reflection layer 300. For example, the display layer 200 and the low-reflection layer 300 may be sealed with the thin-film encapsulation layer 400. The thin-film encapsulation layer 400 may include at least one inorganic encapsulation layer and at least one organic encapsulation layer. Because the organic encapsulation layer provides a more flattened base surface, a defect rate may be reduced even when the touch sensing layer 500 to be described below is formed through a continuous (e.g., a substantially continuous) process.

The touch sensing layer 500 may be on the thin-film encapsulation layer 400. The touch sensing layer 500 may be configured to detect an external input, for example, a touch of a finger and/or an object, such as a stylus pen, and the display apparatus 1 may be configured to obtain coordinate information corresponding to a touch position. The touch sensing layer 500 may include touch electrodes and trace lines connected to the touch electrodes. In the disclosure, an operating method of the touch sensing layer 500 is not particularly limited, and the touch sensing layer 500 may be configured to sense an external input by using a mutual capacitance method or a self-capacitance method.

The touch sensing layer 500 may be on the thin-film encapsulation layer 400. In an embodiment, the touch sensing layer 500 may be directly on the thin-film encapsulation layer 400. An expression “A is directly on B” means that no separate adhesive layer or adhesive member is between A and B. After A is provided, B may be formed on a base surface of A through a continuous process. In one or more embodiments, after the touch sensing layer 500 is separately formed, the touch sensing layer 500 may be bonded on the thin-film encapsulation layer 400 through an adhesive layer, such as an optically clear adhesive (OCA).

The anti-reflection layer 600 may be on the touch sensing layer 500. The anti-reflection layer 600 may reduce the reflectance of light (external light) incident toward the display apparatus 1.

The cover window CW may be on the anti-reflection layer 600. The cover window CW may be configured to protect elements under the cover window CW. The cover window CW may be bonded to the upper surface of the anti-reflection layer 600 by using an OCA.

Referring to FIG. 3B, the display apparatus 1 according to an embodiment may include an encapsulation substrate 700 instead of the thin-film encapsulation layer 400. For example, the display apparatus 1 may include a substrate 100 (e.g., a first substrate), a display layer 200, a low-reflection layer 300, an anti-reflection layer 600, an encapsulation substrate 700 (e.g., a second substrate), and a sealing member 900.

The display layer 200 may be on the substrate 100. The display layer 200 may include an organic light-emitting diode as a display element, a pixel circuit electrically connected to the organic light-emitting diode, and insulating layers therebetween. The low-reflection layer 300 may be on the display layer 200.

The encapsulation substrate 700 may be above the substrate 100. The encapsulation substrate 700 may include glass and/or polymer resin. Examples of the polymer resin may include polyethersulfone, polyacrylate, polyether imide, polyethylene naphthalate, polyethylene terephthalate, polyphenylene sulfide, polyarylate, polyimide, polycarbonate, and/or cellulose acetate propionate. The encapsulation substrate 700 including the polymer resin may be flexible, rollable, or bendable. The encapsulation substrate 700 may have a multilayer structure including a polymer resin-containing layer and an inorganic layer.

The anti-reflection layer 600 may be directly on the lower surface of the encapsulation substrate 700 facing the substrate 100. The expression “the anti-reflection layer 600 is directly on the lower surface of the encapsulation substrate 700” may mean that the anti-reflection layer 600 is formed directly on the encapsulation substrate 700, and then, the substrate 100 and the encapsulation substrate 700 are bonded to each other so that the anti-reflection layer 600 is between the substrate 100 and the encapsulation substrate 700.

The substrate 100 may be connected to the encapsulation substrate 700 through the sealing member 900. The sealing member 900 may be in a non-display area NDA so as to surround the display area DA. For example, in a plan view, the sealing member 900 may be outside the display area DA to form a closed loop. In this case, the sealing member 900 may completely block the display area DA from the outside. The sealing member 900 may include a sealant, frit, and/or the like.

In an embodiment, a filler 800 may be in a gap between the substrate 100 and the encapsulation substrate 700.

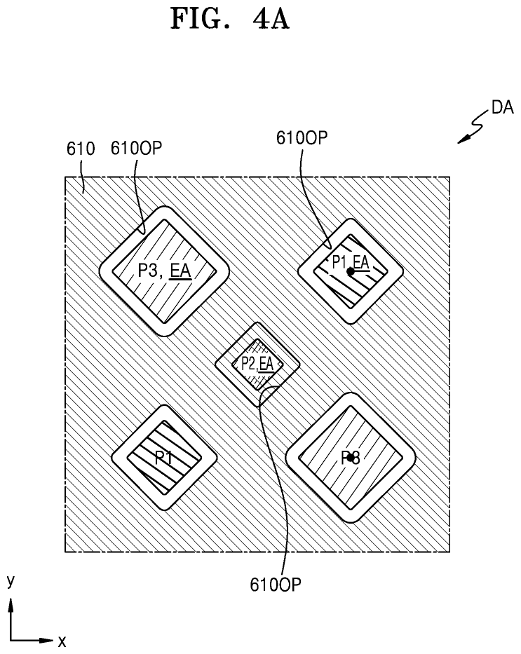

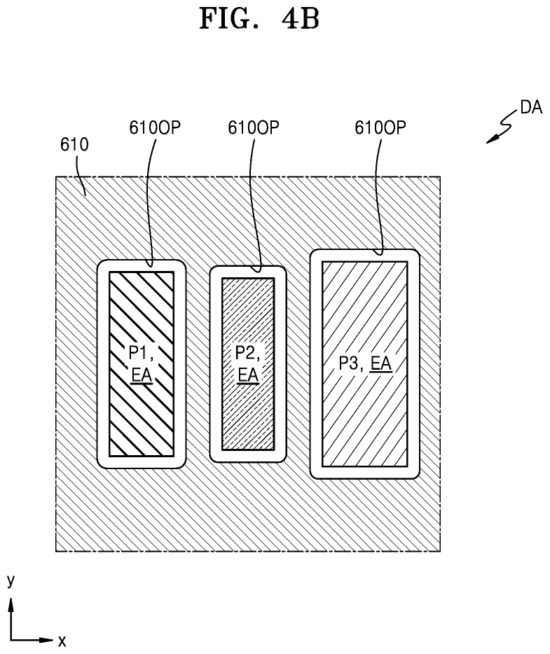

FIGS. 4A-4B are respectively plan views schematically illustrating pixel arrangements of a display apparatus, according to embodiments.

Referring to FIG. 4A, the display apparatus may include a plurality of pixels in a display area DA, and the pixels may include a first pixel P1, a second pixel P2, and a third pixel P3, which emit different colors from each other. For example, the first pixel P1 may emit red light, the second pixel P2 may emit green light, and the third pixel P3 may emit blue light. However, the disclosure is not limited thereto. Various suitable modifications may be made thereto. For example, the first pixel P1 may emit blue light, the second pixel P2 may emit green light, and the third pixel P3 may emit red light.

In a plan view, the first pixel P1, the second pixel P2, and the third pixel P3 may each have a polygonal shape. Although FIG. 4A illustrates that the first pixel P1, the second pixel P2, and the third pixel P3 each have a rectangular shape with round corners, the disclosure is not limited thereto. As another example, the first pixel P1, the second pixel P2, and the third pixel P3 may each have a circular or elliptical shape.

The first pixel P1, the second pixel P2, and the third pixel P3 may have different sizes from each other. For example, the area of the second pixel P2 may be less than the area of each of the first and third pixels P1 and P3, and the area of the first pixel P1 may be greater than the area of the third pixel P3. Various suitable modifications may be made thereto. In another embodiment, the first pixel P1, the second pixel P2, and the third pixel P3 may have substantially the same size as each other.

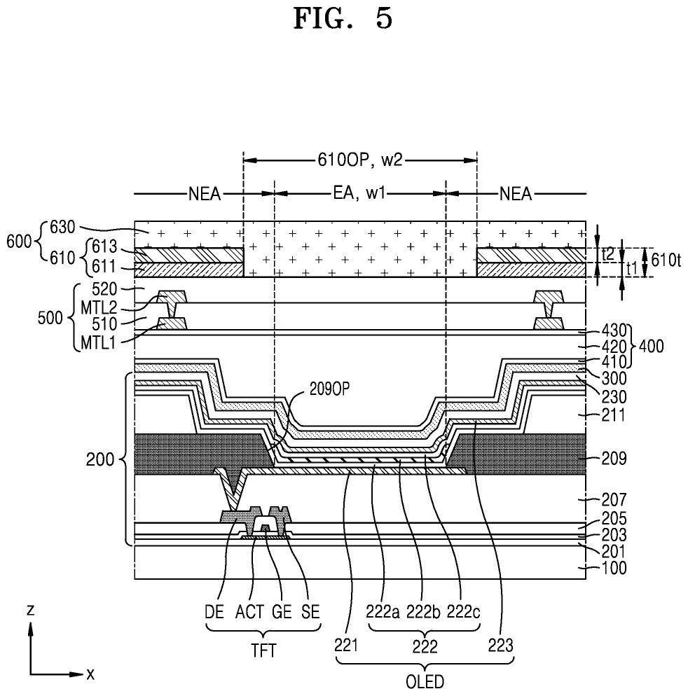

In the present specification, the size of each of the first pixel P1, the second pixel P2, and the third pixel P3 refer to the size of the emission area EA of the display element that implements each pixel, and the emission area EA may be defined by an opening (see 209OP of FIG. 5) of a pixel defining layer (see 209 of FIG. 5).

On the other hand, a light blocking layer 610 above a display element layer has openings 610OP corresponding to the pixels. The openings 610OP may be defined by removing portions of the light blocking layer 610, and light from the display element may be emitted to the outside through the openings 610OP. Because a body portion of the light blocking layer 610 includes a material that reflects and/or offsets external light, visibility of the display apparatus may be improved.

In a plan view, the openings 610OP of the light blocking layer 610 may surround the first pixel P1, the second pixel P2, and the third pixel P3, respectively. In an embodiment, the openings 610OP of the light blocking layer 610 may each have a rectangular shape with round corners. The areas of the openings 610OP of the light blocking layer 610 respectively corresponding to the first pixel P1, the second pixel P2, and the third pixel P3 may be greater than the areas of the first, second, and third pixels P1, P2, and P3. However, the disclosure is not limited thereto. The areas of the openings 610OP of the light blocking layer 610 may be substantially the same as the area of the first pixel P1, the second pixel P2, or the third pixel P3 corresponding thereto.

As illustrated in FIG. 4A, the first pixel P1, the second pixel P2, and the third pixel P3 may be arranged in a PENTILE® arrangement structure (e.g., an RGBG matrix, RGBG structure, or RGBG matrix structure). PENTILE® is a duly registered trademark of Samsung Display Co., Ltd. However, the disclosure is not limited thereto. For example, as illustrated in FIG. 4B, the first pixel P1, the second pixel P2, and the third pixel P3 may be arranged in a stripe structure. Also, in another embodiment, the first pixel P1, the second pixel P2, and the third pixel P3 may be arranged in various suitable pixel arrangement structures, for example, in a mosaic structure or a delta structure.

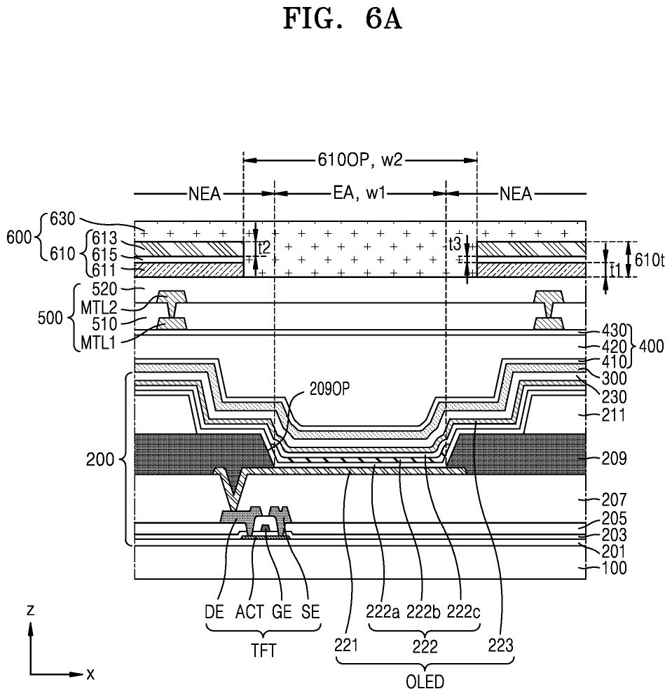

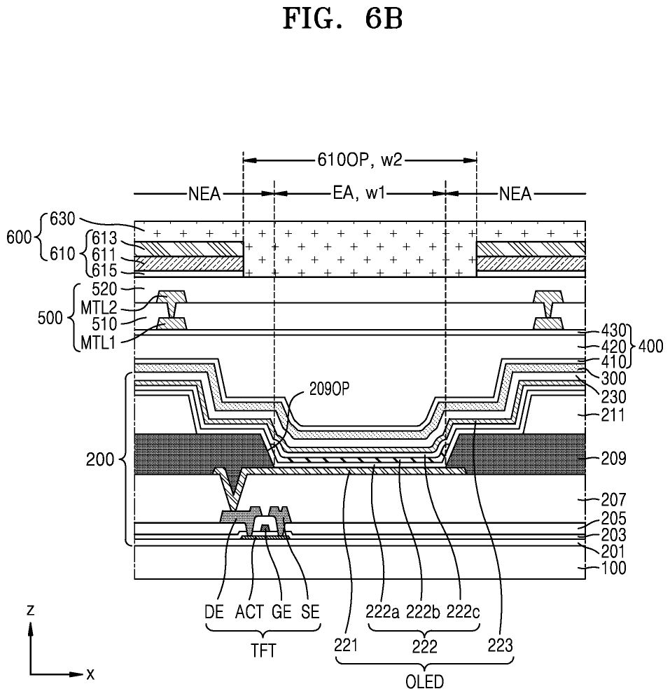

FIG. 5 is a cross-sectional view schematically illustrating a portion of a display apparatus, according to an embodiment, and FIGS. 6A-6B are respectively cross-sectional views schematically illustrating a portion of display apparatuses, according to embodiments.

Referring to FIG. 5, the display apparatus according to an embodiment may include a substrate 100, a display layer 200, a low-reflection layer 300, a thin-film encapsulation layer 400, a touch sensing layer 500, and an anti-reflection layer 600, as described above with reference to FIG. 3A.

The display layer 200 may include an organic light-emitting diode OLED, a thin-film transistor TFT, a buffer layer 201, a gate insulating layer 203, an interlayer insulating layer 205, a planarization layer 207, a pixel defining layer 209, and a spacer 211.

The buffer layer 201 may be on the substrate 100. The buffer layer 201 may reduce or block infiltration of foreign material, ambient air such as moisture, and/or the like from below the substrate 100. Also, the buffer layer 201 may provide a flat surface on the upper surface of the substrate 100. The buffer layer 201 may include silicon oxide (SiO₂) and/or silicon nitride (SiNₓ). In an embodiment, a barrier layer may be between the substrate 100 and the buffer layer 201 so as to prevent or reduce infiltration of ambient air. The barrier layer may include an inorganic insulating material.

The thin-film transistor TFT may be on the buffer layer 201. The thin-film transistor TFT may correspond to the first thin-film transistor (see T1 of FIG. 2) illustrated in FIG. 2. The thin-film transistor TFT may include a semiconductor layer ACT, a gate electrode GE, a source electrode SE, and a drain electrode DE. The source electrode SE or the drain electrode DE of the thin-film transistor TFT may be electrically connected to a pixel electrode 221 of the organic light-emitting diode OLED, and may be configured to drive the organic light-emitting diode OLED.

The semiconductor layer ACT may be on the buffer layer 201 and may include polysilicon. In one or more embodiments, the semiconductor layer ACT may include amorphous silicon. In one or more embodiments, the semiconductor layer ACT may include an oxide of at least one selected from indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer ACT may include a channel region, and a source region and a drain region doped with impurities.

The gate electrode GE, the source electrode SE, and the drain electrode DE may each include various suitable conductive materials. The gate electrode GE may include at least one selected from molybdenum, aluminum, copper, and titanium. For example, the gate electrode GE may have a single molybdenum layer, or may have a three-layer structure including a molybdenum layer, an aluminum layer, and a molybdenum layer. The source electrode SE and the drain electrode DE may each include at least one material selected from copper, titanium, and aluminum. For example, the source electrode SE and the drain electrode DE may each have a three-layer structure including a titanium layer, an aluminum layer, and a titanium layer. In an embodiment, the source electrode SE or the drain electrode DE may be omitted, and the source region or the drain region of the semiconductor layer ACT may function as the source electrode SE or the drain electrode DE.

On the other hand, in order to secure electrical insulation between the semiconductor layer ACT and the gate electrode GE, the gate insulating layer 203 including an inorganic material, such as silicon oxide, silicon nitride, and/or silicon oxynitride, may be between the semiconductor layer ACT and the gate electrode GE. In addition, the interlayer insulating layer 205 including an inorganic material, such as silicon oxide, silicon nitride, and/or silicon oxynitride, may be on the gate electrode GE. The source electrode SE and the drain electrode DE may be on the interlayer insulating layer 205. The insulating layer including the inorganic material, such as the gate insulating layer 203 and the interlayer insulating layer, may be formed by chemical vapor deposition (CVD) and/or atomic layer deposition (ALD).

The planarization layer 207 may be on the thin-film transistor TFT. In an embodiment, after the planarization layer 207 is formed, chemical and/or mechanical polishing may be performed on the upper surface of the planarization layer 207 to provide a flat upper surface. The planarization layer 207 may include general-purpose polymer (e.g., photosensitive polyimide, polyimide, polystyrene (PS), polycarbonate (PC), benzocyclobutene (BCB), hexamethyldisiloxane (HMDSO), and/or polymethylmethacrylate (PMMA)), polymer derivatives having a phenolic group, acrylic polymer, imide-based polymer, aryl ether-based polymer, amide-based polymer, fluorine-based polymer, p-xylene-based polymer, and/or vinyl alcohol-based polymer. Although FIG. 5 illustrates that the planarization layer 207 is a single layer, the planarization layer 207 may be a plurality of layers.

The organic light-emitting diode OLED may be on the planarization layer 207. The organic light-emitting diode OLED may include a pixel electrode 221, an intermediate layer 222, and an opposite electrode 223.

The pixel electrode 221 may be on the planarization layer 207. The pixel electrodes 221 may be spaced apart from each other to correspond to the pixels.

The pixel electrode 221 may be a reflective electrode. For example, the pixel electrode 221 may include a reflective layer or a transparent or semitransparent conductive layer. The reflective layer may include silver (Ag), magnesium (Mg), aluminum (Al), platinum (Pt), palladium (Pd), gold (Au), nickel (Ni), neodymium (Nd), iridium (Ir), chromium (Cr), or any compound thereof. The transparent or semitransparent conductive layer may include at least one material selected from indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 221 may have a stack structure of ITO/Ag/ITO.

The pixel defining layer 209 may be on the pixel electrode 221. The pixel defining layer 209 may have an opening 209OP exposing a central portion of the pixel electrode 221. The pixel defining layer 209 may prevent or reduce occurrence of an electric arc and/or the like at the edge of the pixel electrode 221 by covering the edge of the pixel electrode 221 and increasing the distance between the edge of the pixel electrode 221 and the opposite electrode 223. The emission area EA may be defined by the opening 209OP.

The pixel defining layer 209 may include an organic insulating material. In one or more embodiments, the pixel defining layer 209 may include an inorganic insulating material, such as silicon nitride, silicon oxynitride, and/or silicon oxide. In one or more embodiments, the pixel defining layer 209 may include an organic insulating material and an inorganic insulating material.

In an embodiment, the pixel defining layer 209 may include a light blocking material and may be provided in black. The light blocking material may include carbon black, carbon nanotubes, a resin and/or paste including black dye, metal particles (e.g., nickel, aluminum, molybdenum, and/or any alloy thereof), metal oxide particles (e.g., chromium oxide), and/or metal nitride particles (e.g., chromium nitride). When the pixel defining layer 209 includes a light blocking material, the reflection of external light due to the metal structures below the pixel defining layer 209 may be reduced. However, the disclosure is not limited thereto. In another embodiment, the pixel defining layer 209 may not include a light blocking material, but may include a light-transmitting organic insulating material.

The spacer 211 may be on the pixel defining layer 209. The spacer 211 may include an organic insulating material, such as polyimide. In one or more embodiments, the spacer 211 may include an inorganic insulating material, such as silicon nitride (SiNₓ) and/or silicon oxide (SiO₂), or may include an organic insulating material and an inorganic insulating material.

In an embodiment, the spacer 211 may include the same material as that of the pixel defining layer 209. In this case, the pixel defining layer 209 and the spacer 211 may be formed together in a mask process using a halftone mask or the like. In another embodiment, the spacer 211 may include a material that is different from that of the pixel defining layer 209.

The intermediate layer 222 may be on the pixel electrode 221 and the pixel defining layer 209. The intermediate layer 222 may include a first common layer 222a, an emission layer 222b, and a second common layer 222c.

The emission layer 222b may be in the opening 209OP of the pixel defining layer 209 to correspond to the pixel electrode 221. The emission layer 222b may include an organic material including a fluorescent or phosphorescent material capable of emitting blue light, green light, or red light. The organic material described above may include a low molecular weight organic material and/or a high molecular weight organic material. In one or more embodiments, the emission layer 222b may include an inorganic material including quantum dots and/or the like. As used herein, the term “quantum dot” refers to a crystal of a semiconductor compound, and may include any suitable material capable of emitting light of various suitable emission wavelengths depending on the size of the crystal. The quantum dots may include, for example, Group III-VI semiconductor compounds, Group II-VI semiconductor compounds, Group III-V semiconductor compounds, Group III-VI semiconductor compounds, Group I-III-VI semiconductor compounds, Group IV-VI semiconductor compounds, Group IV elements or compounds, or any combination thereof.

The first common layer 222a and the second common layer 222c may be below and above the emission layer 222b, respectively. The first common layer 222a may include, for example, a hole transport layer (HTL) or may include, for example, an HTL and a hole injection layer (HIL). The second common layer 222c may include, for example, an electron transport layer (ETL), or may include an ETL and an electron injection layer (EIL). In an embodiment, the second common layer 222c may be omitted.

The emission layer 222b may be patterned to correspond to the opening 209OP of the pixel defining layer 209. The first common layer 222a and the second common layer 222c may be integrally formed as a single body to completely cover the substrate 100. In other words, the first common layer 222a and the second common layer 222c may be integrally formed as a single body to completely cover the pixels (see P of FIG. 1) on the display area (see DA of FIG. 1).

The opposite electrode 223 may be on the intermediate layer 222. The opposite electrode 223 may include a conductive material (e.g., an electrically conductive material) having a low work function. For example, the opposite electrode 223 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), ytterbium (Yb), and/or any alloy thereof. For example, the opposite electrode 223 may include AgMg and/or AgYb. In one or more embodiments, the opposite electrode 223 may further include a layer including ITO, IZO, ZnO, and/or In₂O₃ on the (semi)transparent layer including the material described above. The layers from the pixel electrode 221 to the opposite electrode 223 may constitute the organic light-emitting diode OLED.

In an embodiment, the display apparatus 1 may further include a capping layer 230 on the organic light-emitting diode OLED. The capping layer 230 may improve the light emission efficiency of the organic light-emitting diode OLED, based on the principle of constructive interference. The capping layer 230 may include, for example, a material having a refractive index of 1.6 or more for light having a wavelength of 589 nm.

The capping layer 230 may be an organic capping layer including an organic material, an inorganic capping layer including an inorganic material, or a composite capping layer including an organic material and an inorganic material. For example, the capping layer 230 may include carbocyclic compounds, heterocyclic compounds, amine group-containing compounds, porphine derivatives, phthalocyanine derivatives, naphthalocyanine derivatives, alkali metal complexes, alkaline earth metal complexes, or any combination thereof. The carbocyclic compounds, the heterocyclic compounds, and the amine group-containing compounds may be optionally substituted with a substituent including O, N, S, Se, Si, F, Cl, Br, I, or any combination thereof.

The low-reflection layer 300 may be on the capping layer 230. Because the capping layer 230 may be on the organic light-emitting diode OLED, it may be stated that the low-reflection layer 300 is on the organic light-emitting diode OLED. The low-reflection layer 300 may include an inorganic material having low reflectivity. In an embodiment, the low-reflection layer 300 may include a metal and/or a metal oxide. When the low-reflection layer 300 includes a metal, the low-reflection layer 300 may include, for example, ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or any combination thereof. Also, when the low-reflection layer 300 includes a metal oxide, the low-reflection layer 300 may include, for example, SiO₂, TiO₂, ZrO₂, Ta₂O₅, HfO₂, Al₂O₃, ZnO, Y₂O₃, BeO, MgO, PbO₂, WO₃, SiNₓ, LiF, CaF₂, MgF₂, CdS, or any combination thereof.

In an embodiment, an extinction coefficient (k) of the inorganic material included in the low-reflection layer 300 may be greater than 0.5 and less than or equal to 4.0 (0.5<k≤4.0). Also, the inorganic material included in the low-reflection layer 300 may have a refractive index (n) of 1 or more (n≥1.0).

The low-reflection layer 300 may reduce external light reflectance by inducing destructive interference between light incident on the inside of the display apparatus and light reflected from the metal below the low-reflection layer 300. Accordingly, display quality and visibility of the display apparatus may be improved by reducing external light reflectance of the display apparatus through the low-reflection layer 300.

Although FIG. 5 illustrates a structure in which the low-reflection layer 300 is arranged on the entire surface of the substrate 100, like the opposite electrode 223 and the capping layer 230, the disclosure is not limited thereto. For example, the low-reflection layer 300 may be patterned for each pixel.

The thin-film encapsulation layer 400 may be on the low-reflection layer 300. The thin-film encapsulation layer 400 may include at least one inorganic encapsulation layer and at least one organic encapsulation layer. For example, the thin-film encapsulation layer 400 may include a first inorganic encapsulation layer 410, an organic encapsulation layer 420, and a second inorganic encapsulation layer 430, which are sequentially stacked in this stated order.

The first inorganic encapsulation layer 410 and the second inorganic encapsulation layers 430 may each include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO). The first inorganic encapsulation layer 410 and the second inorganic encapsulation layer 430 may each have a single-layer or multilayer structure including the inorganic insulating material described above.

The organic encapsulation layer 420 may reduce internal stress of the first inorganic encapsulation layer 410 and/or the second inorganic encapsulation layer 430. The organic encapsulation layer 420 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, acrylic resin (e.g., polymethylmethacrylate, polyacrylic acid, etc.), or any combination thereof.

The organic encapsulation layer 420 may be formed by applying a flowable material including monomers and then reacting to form a polymer by bonding the monomers using heat and/or light, such as ultraviolet light. In one or more embodiments, the organic encapsulation layer 420 layer may be formed by applying a polymer material.

Even when cracks occur in the thin-film encapsulation layer 400 through the multilayer structure described above, the thin-film encapsulation layer 400 may prevent or reduce connection of such cracks to each other between the first inorganic encapsulation layer 410 and the organic encapsulation layer 420 or between the organic encapsulation layer 420 and the second inorganic encapsulation layer 430. Therefore, it is possible to prevent, minimize, or reduce formation of a path through which ambient moisture and/or oxygen penetrates into the display area DA. Also, the reflective color of the display apparatus may be adjusted by changing the thickness of each layer of the thin-film encapsulation layer 400 and the reflectance according to the wavelength band of external light.

The touch sensing layer 500 may be on the thin-film encapsulation layer 400. The touch sensing layer 500 may include a first conductive layer MTL1, a first touch insulating layer 510, a second conductive layer MTL2, and a second touch insulating layer 520. The first conductive layer MTL1 may be directly on the thin-film encapsulation layer 400. In this case, the first conductive layer MTL1 may be directly on the second inorganic encapsulation layer 430 of the thin-film encapsulation layer 400. However, the disclosure is not limited thereto.

For example, the touch sensing layer 500 may include an insulating layer between the first conductive layer MTL1 and the thin-film encapsulation layer 400. The insulating layer may be on the second inorganic encapsulation layer 430 of the thin-film encapsulation layer 400 and may provide a flat base surface to the first conductive layer MTL1 and/or the like. In this case, the first conductive layer MTL1 may be directly on the insulating layer. The insulating layer may include an inorganic insulating material, such as silicon oxide (SiO₂), silicon nitride (SiNₓ), and/or silicon oxynitride (SiON). In one or more embodiments, the insulating layer may include an organic insulating material.

In an embodiment, the first touch insulating layer 510 may be on the first conductive layer MTL1, and the second conductive layer MTL2 may be on the first touch insulating layer 510. The second conductive layer MTL2 may function as a touch electrode configured to sense a touch input of a user. The first conductive layer MTL1 may function as a connection electrode configured to connect the patterned second conductive layer MTL2 in one direction. In an embodiment, both the first conductive layer MTL1 and the second conductive layer MTL2 may act as sensors. The first conductive layer MTL1 and the second conductive layer MTL2 may be electrically connected to each other through a contact hole passing through the first touch insulating layer 510.

In an embodiment, the first conductive layer MTL1 and the second conductive layer MTL2 may each have, for example, a mesh structure that allow light emitted from the organic light-emitting diode OLED to pass therethrough. In this case, the first conductive layer MTL1 and the second conductive layer MTL2 may be in the non-emission area NEA so as not to overlap the emission area EA of the organic light- emitting diode OLED.

The first conductive layer MTL1 and the second conductive layer MTL2 may each include a metal layer and/or a transparent conductive layer. The metal layer may include molybdenum (Mo), silver (Ag), titanium (Ti), copper (Cu), aluminum (Al), and/or any alloy thereof. The transparent conductive layer may include a transparent conductive oxide, such as indium tin oxide (ITO), indium zinc oxide (IZO), zinc oxide (ZnO), and/or indium tin zinc oxide (ITZO). In addition, the transparent conductive layer may include a conductive polymer, such as PEDOT, metal nanowires, carbon nanotubes, and/or graphene.

In an embodiment, the second touch insulating layer 520 may be on the second conductive layer MTL2. The first touch insulating layer 510 and the second touch insulating layer 520 may each include an inorganic insulating material and/or an organic insulating material. The inorganic insulating material may include at least one material selected from silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The organic insulating material may include at least one material selected from acrylic resin, methacrylic resin, polyisoprene, vinyl resin, epoxy-based resin, urethane-based resin, cellulose-based resin, and perylene-based resin.

The anti-reflection layer 600 may be on the touch sensing layer 500. The anti-reflection layer 600 may include a light blocking layer 610 and a reflection control layer 630.

The light blocking layer 610 may include a first sub-light blocking layer 611 on the touch sensing layer 500, and a second sub-light blocking layer 613 on the first sub-light blocking layer 611. The light blocking layer 610 may have an opening 610OP overlapping the emission area EA and passing through the first sub-light blocking layer 611 and the second sub-light blocking layer 613. In other words, the first sub-light blocking layer 611 and the second sub-light blocking layer 613 may define the opening 610OP overlapping the emission area EA.

In an embodiment, a second width w2 of the opening 610OP of the light blocking layer 610 may be greater than a first width w1 of the opening 209OP of the pixel defining layer 209 defining the emission area EA. However, the disclosure is not limited thereto, and the second width w2 of the opening 610OP of the light blocking layer 610 may be equal to or less than the first width w1 of the opening 209OP of the pixel defining layer 209.

A body portion of the light blocking layer 610 outside the opening 610OP may overlap the non-emission area NEA. The body portion of the light blocking layer 610 refers to a portion where the first sub-light blocking layer 611 and the second sub-light blocking layer 613 overlap each other and have a set or certain volume (thickness). At least a portion of light emitted from the organic light-emitting diode OLED and external light incident from the outside of the display apparatus may be reflected or offset by the body portion of the light blocking layer 610.

The first sub-light blocking layer 611 may include a metal material having a light reflectance of 95% or more. For example, the first sub-light blocking layer 611 may include aluminum (Al), super-aluminum (s-Al), silver (Ag), chromium (Cr), tungsten (W), or any combination thereof. The first sub-light blocking layer 611 may have a first thickness t1 in a direction (z direction) perpendicular (e.g., substantially perpendicular) to the upper surface of the substrate 100. The first thickness t1 may be about 40 Å to about 1,500 Å.

The second sub-light blocking layer 613 may include a metal material and/or a metal oxide having a high extinction coefficient (k). An extinction coefficient (k) of the metal material and/or the metal oxide may be greater than 0.5 and less than or equal to 4.0 (0.5<k≤4.0). For example, the second sub-light blocking layer 613 may include copper oxide (CuO), calcium oxide (CaO), molybdenum oxide (MoOₓ), zinc oxide (ZnO), molybdenum-titanium-oxide (MTO), or any combination thereof. The second sub-light blocking layer 613 may have a second thickness t2 in a direction (z direction) perpendicular (e.g., substantially perpendicular) to the upper surface of the substrate 100. The second thickness t2 may be about 150 Å to about 1,000 Å.

Referring to FIGS. 6A-6B, the light blocking layer 610 may further include an auxiliary layer 615. The auxiliary layer 615 may control the phase of reflected light. The auxiliary layer 615 may have a single-layer or multilayer structure including indium tin oxide (ITO), indium zinc oxide (IZO), and/or silicon nitride (SiNₓ). For example, the auxiliary layer 615 may include a double layer of ITO/SiNₓ. The auxiliary layer 615 may have a third thickness t3 in a direction (z direction) perpendicular (e.g., substantially perpendicular) to the upper surface of the substrate 100. The third thickness t3 may be about 50 Å to about 100 Å.

The auxiliary layer 615 may be in contact with the first sub-light blocking layer 611. For example, as illustrated in FIG. 6A, the auxiliary layer 615 may be between the first sub-light blocking layer 611 and the second sub-light blocking layer 613. In another embodiment, as illustrated in FIG. 6B, the auxiliary layer 615 may be between the second touch insulating layer 520 and the first sub-light blocking layer 611. In another embodiment, a plurality of auxiliary layers 615 may be provided. The auxiliary layers 615 may be between the second touch insulating layer 520 and the first sub-light blocking layer 611 and between the first sub-light blocking layer 611 and the second sub-light blocking layer 613.

External light incident toward the upper surface of the substrate 100 may be reflected by the first sub-light blocking layer 611. In this case, light reflected from the upper surface of the first sub-light blocking layer 611 may be offset by interference of light reflected from the upper surface of the second sub-light blocking layer 613. Therefore, the wavelength band of light to be offset may be controlled by adjusting the first thickness t1 of the first sub-light-blocking layer 611 and the second thickness t2 of the second sub-light blocking layer 613.

As a comparative example, when the light blocking layer includes a resin containing a light blocking material, the total thickness of the light blocking layer may be about 1 μm or more. In this case, light emitted from the display element may be blocked by the light blocking layer, and thus, side luminance of the display apparatus may be reduced. However, in the display apparatuses according to embodiments of the present disclosure, because the thickness 610t of the light blocking layer 610 is about 0.4 μm or less, the difference between front luminance and side luminance of the display apparatus may be reduced.

The reflection control layer 630 may be on the light blocking layer 610. The reflection control layer 630 may cover the upper surface of the light blocking layer 610 and may fill the opening 610OP of the light blocking layer 610. The reflection control layer 630 may be in direct contact with the second touch insulating layer 520 exposed through the opening 610OP of the light blocking layer 610.

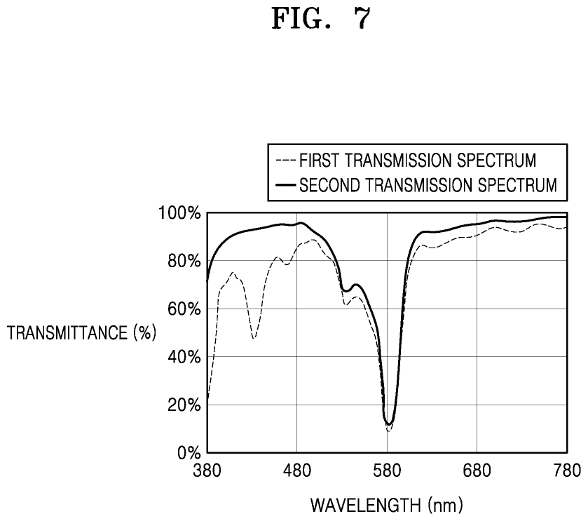

The reflection control layer 630 may selectively absorb light belonging to a partial wavelength band among light reflected from the inside of the display apparatus or external light incident from the outside of the display apparatus. Hereinafter, the reflection control layer 630 will be described in more detail with reference to FIG. 7.

FIG. 7 is a graph showing a transmission spectrum of the reflection control layer 630, according to an embodiment.

Referring to FIGS. 5 and 7, the reflection control layer 630 may have a first transmission spectrum or a second transmission spectrum. In an embodiment, when the reflection control layer 630 has the first transmission spectrum, the reflection control layer 630 may absorb light belonging to a first wavelength band of 585 nm to 605 nm. In this case, the transmission spectrum of the reflection control layer 630 may have a light transmittance of 40% or less in the first wavelength band. In another embodiment, when the reflection control layer 630 has the second transmission spectrum, the reflection control layer 630 may absorb light belonging to the first wavelength band of 585 nm to 605 nm and light belonging to a second wavelength band of 420 nm to 445 nm. In this case, the second transmittance spectrum of the reflection control layer 630 may have a light transmittance of 40% or less in the first wavelength band and a light transmittance of 70% or less in the second wavelength band. In one or more embodiments, the reflection control layer 630 may absorb light of a wavelength out of a red, green, or blue emission wavelength range emitted from the display element. As described above, because the reflection control layer 630 absorbs light of a wavelength that does not belong to the red, green, or blue wavelength range of the organic light-emitting diode OLED, it is possible to prevent or reduce a decrease in luminance of the display apparatus, to prevent or reduce a decrease in luminescence efficiency of the display apparatus, and to improve visibility.

On the other hand, in another embodiment, the reflection control layer 630 may desirably or necessarily absorb the second wavelength band of 585 nm to 605 nm and may selectively absorb the first wavelength band of 480 nm to 500 nm. For example, the reflection control layer 630 may not absorb the first wavelength band. In some cases, the reflection control layer 630 may absorb at least a portion of the first wavelength band so as to control final reflection visibility. In one or more embodiments, the reflection control layer 630 may selectively absorb other wavelength bands (e.g., 410 nm to 440 nm).

In an embodiment, the reflection control layer 630 may include an organic material layer including a dye, a pigment, or any combination thereof. The reflection control layer 630 may include tetraazaporphyrin (TAP)-based compounds, porphyrin-based compounds, metal porphyrin-based compounds, oxazine-based compounds, squarylium-based compounds, triarylmethane-based compounds, polymethine-based compounds, traquinone-based compounds, phthalocyanine-based compounds, azo-based compounds, perylene-based compounds, xanthene-based compounds, diimmonium-based compounds, dipyrromethene-based compounds, cyanine-based compounds, and/or any combination thereof.

For example, the reflection control layer 630 may include a compound represented by one selected from Formulae 1 to 4 below. Formulae 1 to 4 may be chromophore structures corresponding to some compounds described above. Formulae 1 to 4 are only examples, and the disclosure is not limited thereto.

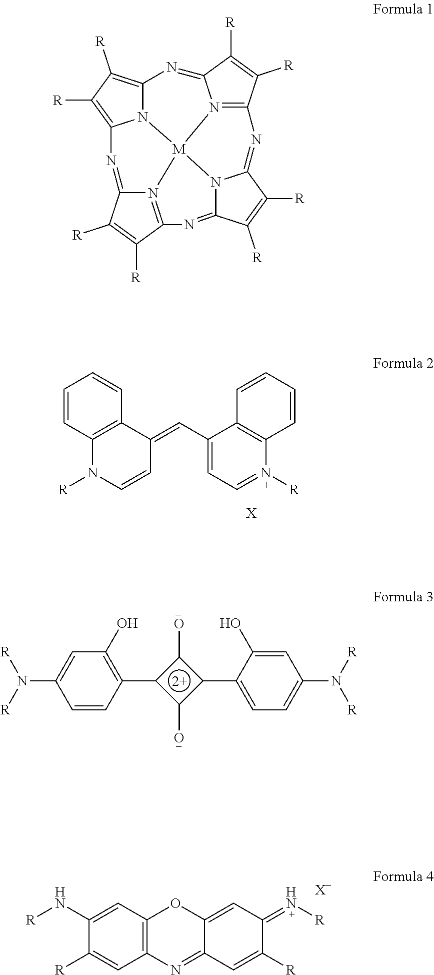

In Formulae 1 to 4,
M may be a metal,
X⁻ may be a monovalent anion, and
R(s) may be identical to or different from each other and may each independently be selected from: hydrogen, deuterium (-D), —F, —Cl, —Br, —I, a hydroxyl group, a cyano group, a nitro group; a C₁-C₆₀ alkyl group, a C₂-C₆₀ alkenyl group, a C₂-C₆₀ alkynyl group, or a C₁-C₆₀ alkoxy group, unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ may each independently be selected from: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, X⁻ may be a halide ion, a carboxylate ion, a nitrate ion, a sulfonate ion, or a bisulfate ion.

For example, X⁻ may be F⁻, Cl⁻, Br⁻, I⁻, CH3COO⁻, NO3⁻, HSO4⁻, a propionate ion, a benzene sulfonate ion, or the like.

In order to reduce the reflection of external light, the display apparatus according to the present embodiment does not use a polarizer (polarizing film), and employs the low-reflection layer 300 and the reflection control layer 630.

As a comparative example, when a polarizer is used to reduce the reflection of external light, transmittance of light emitted from the display element may be significantly reduced by the polarizer. When a color filter corresponding to the color of each pixel is used to reduce the reflection of external light, process costs may increase due to many (e.g., increased) process steps.

Because the display apparatus according to the present embodiment includes the low-reflection layer 300 and the reflection control layer 630, which are commonly applied to each pixel, the light transmittance may be increased and the reflection of external light may be reduced.

The reflection control layer 630 may be over the entire surface of the display area DA. In an embodiment, the reflection control layer 630 may have a transmittance of about 64% to about 72%. The transmittance of the reflection control layer 630 may be controlled according to the amount of pigment and/or dye included in the reflection control layer 630.

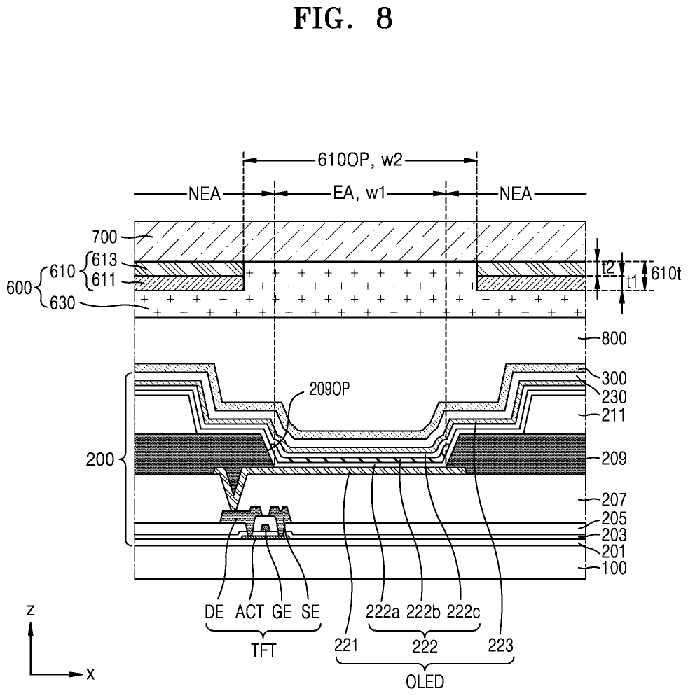

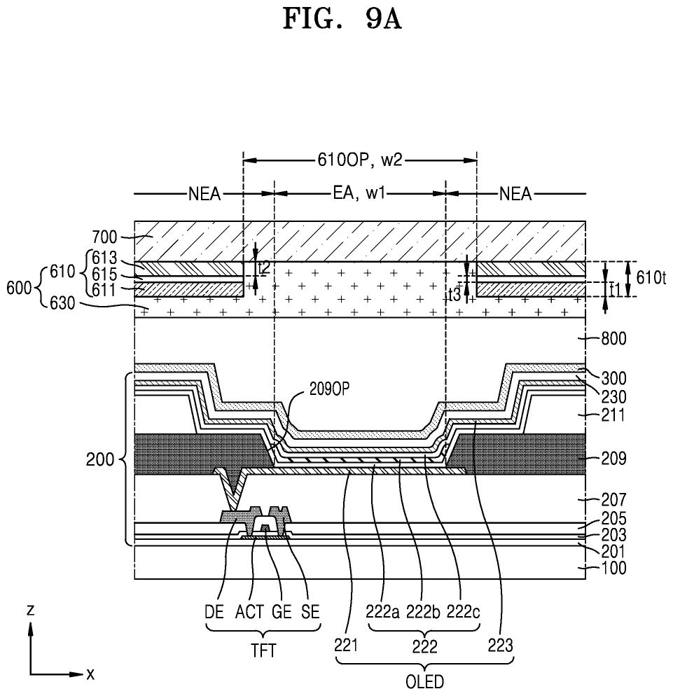

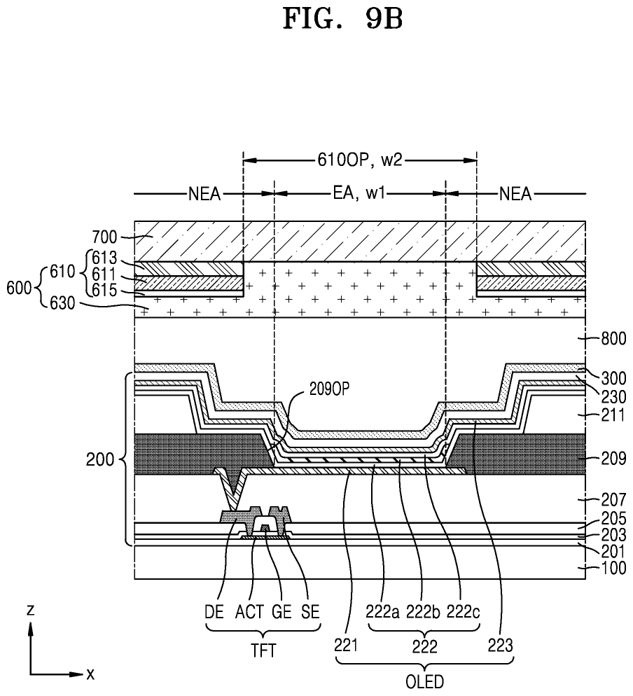

FIG. 8 is a cross-sectional view schematically illustrating a portion of a display apparatus, according to an embodiment, and FIGS. 9A-9B are respectively cross-sectional views schematically illustrating a portion of display apparatuses, according to embodiments.

The display apparatus illustrated in FIG. 8 may include a substrate 100, a display layer 200, a low-reflection layer 300, an anti-reflection layer 600, and an encapsulation substrate 700, as described above with reference to FIG. 3B. The substrate 100, the display layer 200, and the low-reflection layer 300 may be substantially the same as or similar to the elements described above with reference to FIG. 5.

Referring to FIG. 8, the encapsulation substrate 700 may be on the substrate 100 with the display layer 200 therebetween. The anti-reflection layer 600 may be on the lower surface of the encapsulation substrate 700 facing the substrate 100 from the encapsulation substrate 700. The expression “the anti-reflection layer 600 is on the lower surface of the encapsulation substrate 700” may mean that the anti-reflection layer 600 is formed directly on the lower surface of the encapsulation substrate 700, and then, the substrate 100 and the encapsulation substrate 700 are bonded to each other so that the anti-reflection layer 600 is between the substrate 100 and the encapsulation substrate 700.

The light blocking layer 610 may be directly on the lower surface of the encapsulation substrate 700. For example, a second sub-light-blocking layer 613 may be on the lower surface of the encapsulation substrate 700, and a first sub-light blocking layer 611 may be on the lower surface of the second sub-light blocking layer 613 facing the substrate 100 from the second sub-light blocking layer 613.

The light blocking layer 610 may have an opening 610OP overlapping the emission area EA and passing through the first sub-light blocking layer 611 and the second sub-light blocking layer 613. In other words, the first sub-light blocking layer 611 and the second sub-light blocking layer 613 may define the opening 610OP overlapping the emission area EA.

In an embodiment, a second width w2 of the opening 610OP of the light blocking layer 610 may be greater than a first width w1 of the opening 209OP of the pixel defining layer 209 defining the emission area EA. However, the disclosure is not limited thereto, and the second width w2 of the opening 610OP of the light blocking layer 610 may be equal to or less than the first width w1 of the opening 209OP of the pixel defining layer 209.

A body portion of the light blocking layer 610 outside the opening 610OP may overlap the non-emission area NEA. The body portion of the light blocking layer 610 refers to a portion where the first sub-light blocking layer 611 and the second sub-light blocking layer 613 overlap each other and have a set or certain volume (thickness). At least a portion of light emitted from the organic light-emitting diode OLED and external light incident from the outside of the display apparatus may be reflected or offset by the body portion of the light blocking layer 610.

The first sub-light blocking layer 611 may include a metal material having a light reflectance of 95% or more. For example, the first sub-light blocking layer 611 may include aluminum (Al), super-aluminum (s-Al), silver (Ag), chromium (Cr), tungsten (W), or any combination thereof. The first sub-light blocking layer 611 may have a first thickness t1 in a direction (z direction) perpendicular (e.g., substantially perpendicular) to the upper surface of the substrate 100. The first thickness t1 may be about 40 Å to about 1,500 Å.

The second sub-light blocking layer 613 may include a metal material and/or a metal oxide having a high extinction coefficient (k). An extinction coefficient (k) of the metal material and/or the metal oxide may be greater than 0.5 and less than or equal to 4.0 (0.5<k≤4.0). For example, the second sub-light blocking layer 613 may include copper oxide (CuO), calcium oxide (CaO), molybdenum oxide (MoOₓ), zinc oxide (ZnO), molybdenum-titanium-oxide (MTO), or any combination thereof. The second sub-light blocking layer 613 may have a second thickness t2 in a direction (z direction) perpendicular (e.g., substantially perpendicular) to the upper surface of the substrate 100. The second thickness t2 may be about 150 Å to about 1,000 Å.

Referring to FIGS. 9A-9B, the light blocking layer 610 may further include an auxiliary layer 615. The auxiliary layer 615 may control the phase of reflected light. The auxiliary layer 615 may have a single-layer or multilayer structure including indium tin oxide (ITO), indium zinc oxide (IZO), and/or silicon nitride (SiNₓ). For example, the auxiliary layer 615 may include a double layer of ITO/SiNₓ. The auxiliary layer 615 may have a third thickness t3 in a direction (z direction) perpendicular (e.g., substantially perpendicular) to the upper surface of the substrate 100. The third thickness t3 may be about 50 Å to about 100 Å.

The auxiliary layer 615 may be in contact with the first sub-light blocking layer 611. For example, as illustrated in FIG. 9A, the auxiliary layer 615 may be between the first sub-light blocking layer 611 and the second sub-light blocking layer 613. In another embodiment, as illustrated in FIG. 9B, the auxiliary layer 615 may be between the reflection control layer 630 and the first sub-light blocking layer 611. In another embodiment, a plurality of auxiliary layers 615 may be provided. The auxiliary layers 615 may be between the reflection control layer 630 and the first sub-light blocking layer 611 and between the first sub-light blocking layer 611 and the second sub-light blocking layer 613.

External light incident toward the upper surface of the substrate 100 may be reflected by the first sub-light blocking layer 611. In this case, light reflected from the upper surface of the first sub-light blocking layer 611 may be offset by interference of light reflected from the upper surface of the second sub-light blocking layer 613. Therefore, the wavelength band of light to be offset may be controlled by adjusting the first thickness t1 of the first sub-light-blocking layer 611 and the second thickness t2 of the second sub-light blocking layer 613.

As a comparative example, when the light blocking layer includes a resin containing a light blocking material, the total thickness of the light blocking layer may be about 1 μm or more. In this case, light emitted from the display apparatus may be blocked by the light blocking layer, and thus, side luminance of the display apparatus may be reduced. However, in the display apparatuses according to embodiments of the present disclosure, because the thickness 610t of the light blocking layer 610 is about 0.4 μm or less, the difference between front luminance and side luminance of the display apparatus may be reduced.

The reflection control layer 630 may be on the lower surface of the light blocking layer 610 facing the substrate 100 from the light blocking layer 610. The reflection control layer 630 may cover the lower surface of the light blocking layer 610 and may fill the opening 610OP of the light blocking layer 610. The reflection control layer 630 may be in direct contact with the encapsulation substrate 700 exposed through the opening 610OP of the light blocking layer 610.

A filler 800 may be between the substrate 100 and the encapsulation substrate 700. For example, the filler 800 may be filled between the anti-reflection layer 600 and the low-reflection layer 300. The filler 800 may include a resin, such as acryl and/or epoxy. In an embodiment, the reflection control layer 630 may be in direct contact with the filler 800.

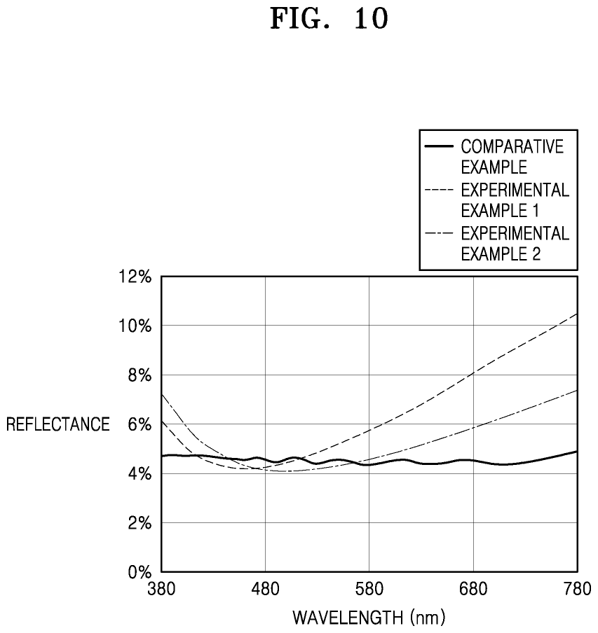

FIG. 10 is a graph showing reflectance for each wavelength in a display apparatus according to a comparative example and display apparatuses according to experimental examples.

The comparative example has substantially the same structure as the display apparatus described above with reference to FIG. 8, but a light blocking layer includes a resin including a light blocking material.

Experimental Example 1 and Experimental Example 2 each have substantially the same structure as the display apparatus described above with reference to FIG. 8. The first sub-light blocking layer (see 611 of FIG. 8) of Experimental Example 1 is an aluminum (Al) layer having a first thickness of about 60 Å, and the second sub-light blocking layer 613 is an MTO layer having a second thickness of about 405 Å. The first sub-light blocking layer (see 611 of FIG. 8) of Experimental Example 2 is a silver (Ag) layer having a first thickness of about 70 Å, and the second sub-light blocking layer 613 is an MTO layer having a second thickness of about 180 Å.

Referring to FIG. 10, it may be seen that the comparative example has a similar reflectance over the entire visible ray wavelength band. On the other hand, in Experimental Examples 1 and 2, it was seen that a minimum reflectance point was located in a wavelength band of about 380 nm to about 580 nm, and Experimental Examples 1 and 2 had asymmetric reflection characteristics with low reflectance in a short wavelength band.

TABLE 1

| | | Aperture | Aperture | Aperture | Aperture | Aperture | Aperture |
|---|---|---|---|---|---|---|---|
| Converted aperture ratio | | ratio 1 | ratio 2 | ratio 3 | ratio 4 | ratio 5 | ratio 6 |
| Red | | 0.58 | 0.58 | 0.58 | 0.66 | 0.66 | 0.75 |
| Green | | 1.0 | 1.0 | 1.0 | 1.0 | 1.0 | 1.0 |
| Blue | | 0.94 | 1.09 | 1.25 | 1.25 | 1.41 | 1.41 |
| Comparative | Reflectance | 7.22% | 7.35% | 7.48% | 7.62% | 7.76% | 7.92% |
| Example | Reflective | 0.302 | 0.301 | 0.300 | 0.301 | 0.300 | 0.302 |
| | color x | | | | | | |
| | Reflective | 0.329 | 0.325 | 0.321 | 0.322 | 0.318 | 0.319 |
| | color y | | | | | | |
| Experimental | Reflectance | 7.34% | 7.43% | 7.52% | 7.63% | 7.72% | 7.86% |
| Example 1 | Reflective | 0.312 | 0.311 | 0.309 | 0.311 | 0.310 | 0.311 |
| | color x | | | | | | |
| | Reflective | 0.330 | 0.326 | 0.322 | 0.323 | 0.319 | 0.320 |
| | color y | | | | | | |
| Experimental | Reflectance | 7.19% | 7.28% | 7.37% | 7.49% | 7.57% | 7.71% |
| Example 2 | Reflective | 0.309 | 0.307 | 0.306 | 0.308 | 0.306 | 0.308 |
| | color x | | | | | | |
| | Reflective | 0.326 | 0.322 | 0.318 | 0.319 | 0.315 | 0.316 |
| | color y | | | | | | |

Table 1 shows a result of measuring reflectance and reflective color coordinates while changing converted aperture ratios of red and blue pixels when an aperture ratio of a green pixel per unit area of the display area of the display apparatus is converted to 1.

Referring to Table 1, it may be seen that, as the converted aperture ratios of the red and blue pixels increase, the reflectance of the comparative example increases significantly, but the reflectance of Experimental Example 1 and the reflectance of Experimental Example 2 less increase. For example, under the condition of aperture ratio 6 in which the converted aperture ratio of the red pixel was 0.75 and the converted aperture ratio of the blue pixel was increased to 1.41, the reflectance of the comparative example was 7.92%, but the reflectance of Experimental Example 1 was 7.86%, and the reflectance of Experimental Example 2 was 7.71%. That is, it was seen that the reflectance of Experimental Examples 1 and 2 was maintained at a low reflectance. Also, it was seen that the x values of the reflective color coordinates of Experimental Examples 1 and 2 were greater than the x value of the reflective color coordinates of Comparative Example under the same converted aperture ratio condition.

As the lifespan of materials constituting the emission layer increases, the aperture ratio of each of the green, red, and blue pixels increases, and the control of reflection characteristics of the display apparatus is required or desired. As illustrated in FIG. 10, when the light blocking layer includes a resin including a light blocking material, it is difficult to control the reflective color of the display apparatus because the display apparatus has a similar reflectance over the entire visible light wavelength range. On the other hand, by controlling the thicknesses of the first sub-light-blocking layer (see 611 of FIG. 8) and the second sub-light-blocking layer (see 613 of FIG. 8), the display apparatuses according to embodiments may change the position of the minimum reflectance point and may control the reflective color of the display apparatus.

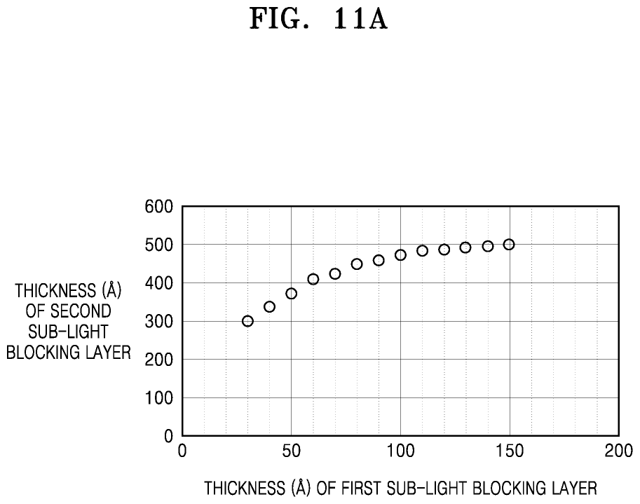

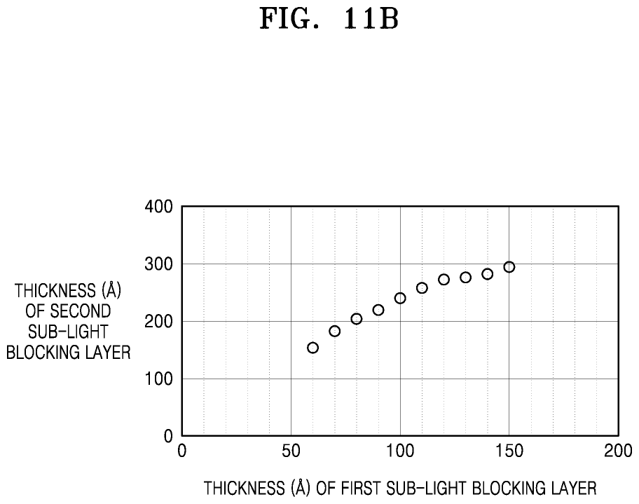

FIGS. 11A-11B are graphs showing a relationship between thicknesses of the first sub-light blocking layer and the second sub-light blocking layer, which have a minimum reflectance in a short wavelength band.

FIG. 11A shows the thicknesses of the first sub-light blocking layer (see 611 of FIG. 8) and the second sub-light blocking layer (see 613 of FIG. 8), which have a minimum reflectance in a short wavelength band (e.g., the circles in the graph represent the combination of respective thicknesses of the first sub-light blocking layer and the second sub-light blocking layer that provide the minimum reflectance in the short wavelength band), when the first sub-light blocking layer (see 611 of FIG. 8) includes aluminum (Al) and the second sub-light blocking layer (see 613 of FIG. 8) includes MTO.

FIG. 11B shows the thicknesses of the first sub-light blocking layer (see 611 of FIG. 8) and the second sub-light blocking layer (see 613 of FIG. 8), which have a minimum reflectance in a short wavelength band (e.g., the circles in the graph represent the combination of respective thicknesses of the first sub-light blocking layer and the second sub-light blocking layer that provide the minimum reflectance in the short wavelength band), when the first sub-light blocking layer (see 611 of FIG. 8) includes silver (Ag) and the second sub-light blocking layer (see 613 of FIG. 8) includes MTO.

When the thickness of the first sub-light blocking layer and the thickness of the second sub-light blocking layer have the same conditions as the points indicated in FIGS. 11A-11B, the minimum reflectance point is located in a wavelength band of about 380 nm to about 580 nm, and the first sub-light blocking layer and the second sub-light blocking layer may have asymmetric reflection characteristics with a low reflectance in a short wavelength band.

According to one or more embodiments, a display apparatus with improved visibility may be implemented. The scope of the disclosure, however, is not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and equivalents thereof.

What is claimed is:

1. A display apparatus comprising:
a substrate;
a display element on the substrate and defining an emission area;
a low-reflection layer on the display element and comprising an inorganic material;
a light blocking layer comprising a first sub-light blocking layer on the low-reflection layer and a second sub-light blocking layer on the first sub-light blocking layer, the light blocking layer having an opening passing through the first sub-light blocking layer and the second sub-light blocking layer to correspond to the emission area; and
a reflection control layer on the light blocking layer and filling the opening,
wherein the first sub-light blocking layer comprises a metal material, and the second sub-light blocking layer comprises a metal material and/or a metal oxide.

2. The display apparatus of claim 1, wherein the first sub-light-blocking layer has a light reflectance of 95% or more, and
the second sub-light-blocking layer has an extinction coefficient (k) greater than 0.5 and less than or equal to 4.0 (0.5<k≤4.0).

3. The display apparatus of claim 2, wherein the first sub-light blocking layer has a first thickness of about 40 Å to about 1,500 Å, and
the second sub-light blocking layer has a second thickness of about 150 Å to about 1,000 Å.

4. The display apparatus of claim 1, wherein the light blocking layer comprises an auxiliary layer in contact with the first sub-light blocking layer, and
the auxiliary layer comprises a transparent conductive material and/or silicon nitride.

5. The display apparatus of claim 4, wherein the auxiliary layer is between the first sub-light blocking layer and the second sub-light blocking layer.

6. The display apparatus of claim 4, wherein the auxiliary layer is between the low-reflection layer and the first sub-light blocking layer.

7. The display apparatus of claim 4, wherein the auxiliary layer has a thickness of about 50 Å to about 100 Å.

8. The display apparatus of claim 1, wherein the low-reflection layer comprises at least one selected from a metal material and a metal oxide, and
the low-reflection layer has a refractive index (n) of 1 or more.

9. The display apparatus of claim 1, further comprising a capping layer on the display element and comprising an organic material,
wherein the low-reflection layer is directly on the capping layer.

10. The display apparatus of claim 1, wherein the reflection control layer comprises a dye, a pigment, or any combination thereof.

11. The display apparatus of claim 1, further comprising:
a thin-film encapsulation layer on the low-reflection layer; and
a touch sensing layer on the thin-film encapsulation layer,
wherein the light blocking layer is on the touch sensing layer.

12. A display apparatus comprising:
a first substrate;
a display element on the first substrate and defining an emission area;
a low-reflection layer on the display element and comprising an inorganic material;
a second substrate above the first substrate with the display element and the low-reflection layer therebetween;
a light blocking layer comprising a second sub-light blocking layer on a lower surface of the second substrate facing the first substrate and a first sub-light blocking layer on a lower surface of the second sub-light blocking layer facing the first substrate, the light blocking layer having an opening passing through the first sub-light blocking layer and the second sub-light blocking layer to correspond to the emission area; and
a reflection control layer between the light blocking layer and the low-reflection layer and filling the opening,
wherein the first sub-light blocking layer comprises a metal material, and the second sub-light blocking layer comprises a metal material and/or a metal oxide.

13. The display apparatus of claim 12, wherein the first sub-light-blocking layer has a light reflectance of 95% or more, and
the second sub-light-blocking layer has an extinction coefficient (k) greater than 0.5 and less than or equal to 4.0 (0.5<k≤4.0).

14. The display apparatus of claim 13, wherein the first sub-light blocking layer has a first thickness of about 40 Å to about 1,500 Å, and
the second sub-light blocking layer has a second thickness of about 150 Å to about 1,000 Å.

15. The display apparatus of claim 12, wherein the light blocking layer comprises an auxiliary layer in contact with the first sub-light blocking layer, and
the auxiliary layer comprises a transparent conductive material and/or silicon nitride.

16. The display apparatus of claim 15, wherein the auxiliary layer has a thickness of about 50 Å to about 100 Å.

17. The display apparatus of claim 12, wherein the low-reflection layer comprises at least one selected from a metal material and a metal oxide, and
the low-reflection layer has a refractive index (n) of 1 or more.

18. The display apparatus of claim 12, further comprising a capping layer on the display element and comprising an organic material,
wherein the low-reflection layer is directly on the capping layer.

19. The display apparatus of claim 12, wherein the reflection control layer comprises a dye, a pigment, or any combination thereof.

20. The display apparatus of claim 12, further comprising a filler between the low-reflection layer and the reflection control layer.
